(19) United States
(12) Patent Application Publication
(10) Pub. No.: US 2026/0255968 A1
(43) Pub. Date: Aug. 27, 2026

(54) FIN STRUCTURE AND SOLID-LIQUID PHASE CHANGE MATERIAL

(71) Applicant: QUALCOMM Incorporated, San Diego, CA (US)

(72) Inventors: Le GAO, San Diego, CA (US); Youmin YU, Escondido, CA (US); Nader NIKFAR, San Diego, CA (US)

(21) Appl. No.: 19/060,232

(22) Filed: Feb. 21, 2025

(51) Int. Cl. H01L 23/427; H01L 23/00; H01L 23/16

(52) U.S. Cl. CPC H10W 40/73; H10W 42/121; H10W 76/40

(57) ABSTRACT

Disclosed are semiconductor packages. In one or more aspects, a thermally conductive lid is provided to transfer heat away from a die during operations. The lid contains solid-liquid phase change material (SLPCM). The SLPCM changes phase from solid to liquid while maintaining constant temperature. Thus, the lid with the SLPCM is more effective as a heat sink than the conventional solid lids.

### BACKGROUND OF THE DISCLOSURE

### 1. Field of the Disclosure

This disclosure relates generally to die packages or modules, and more specifically, but not exclusively, to fin structure and solid-liquid phase change material (SLPCM) to improve package thermal improvement in die packages and fabrication techniques thereof.

### 2. Description of the Related Art

Integrated circuit (IC) technology has achieved great strides in advancing computing power through miniaturization of active components. Conventional lidded packages are mostly used in high-power applications such as in automotive platforms. However, when junction temperature Tj gets high, thermal interface material (TIM) delamination can occur. As a result, package warpage can grow beyond specification, which in turn can cause overheating. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a die on a substrate. The semiconductor package may also comprise a thermal interface material (TIM) on an upper surface of the die. The semiconductor package may further comprise a lid on the TIM. The lid may comprise a chassis and a cover on the chassis. The chassis and the cover may define an internal volume of the lid. The lid may also comprise a solid-liquid phase change material (SLPCM) within the internal volume of the lid.

A method of fabricating a semiconductor package is disclosed. The method may comprise providing a die on a substrate. The method may also comprise forming a thermal interface material (TIM) on an upper surface of the die. The method may further comprise providing a lid on the TIM. The lid may comprise a chassis and a cover on the chassis. The chassis and the cover may define an internal volume of the lid. The lid may also comprise a solid-liquid phase change material (SLPCM) within the internal volume of the lid.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of a conventional semiconductor package.

FIG. 2A illustrates a cross-sectional view of a semiconductor package in accordance with one or more aspects of the disclosure.

FIG. 2B illustrates a cross-sectional view of another semiconductor package in accordance with one or more aspects of the disclosure.

FIG. 3A-3B illustrate an example of a lid used in semiconductor package in accordance with one or more aspects of the disclosure.

FIG. 4A-4D example stages of fabricating the semiconductor package of FIG. 2A in accordance with at one or more aspects of the disclosure.

FIG. 5A-5C example stages of fabricating the semiconductor package of FIG. 2B in accordance with at one or more aspects of the disclosure.

FIG. 6-7 illustrate flow charts of example methods of manufacturing a semiconductor package in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, The semiconductor package may comprise a die on a substrate. The semiconductor package may also comprise a thermal interface material (TIM) on an upper surface of the die. The semiconductor package may further comprise a lid on the TIM. The lid may comprise a chassis and a cover on the chassis. The chassis and the cover may define an internal volume of the lid. The lid may also comprise a solid-liquid phase change material within the internal volume of the lid. This can improve thermal performance of the semiconductor package.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

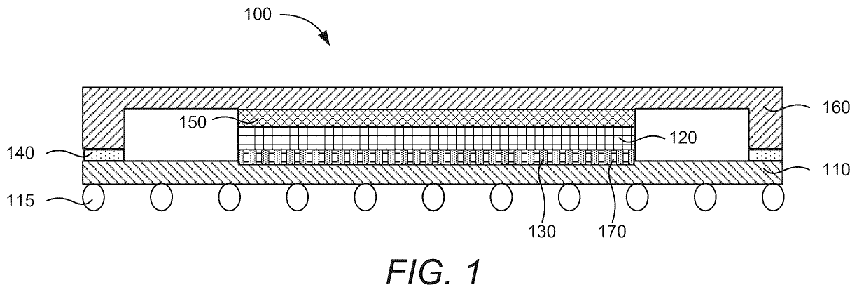

FIG. 1 illustrates a cross-sectional view of a conventional semiconductor package 100. The conventional semiconductor package 100 includes a substrate 110 with balls 115 of a ball grid array (BGA) formed on a lower surface of the substrate 110. The semiconductor package 100 also includes a die 120 on the substrate 110. The die 120 includes microbumps 130 to electrically connect the die 120 with the substrate 110. Underfill 170 fills the space between the substrate 110 and the die 120 not occupied by the microbumps 130.

A thermal interface material (TIM) 150 is on an upper surface of the die 120. A lid 160 is on the TIM 150. In this way, heat generated by the die 120 during operation can be dissipated by the lid 160. Adhesives 140 are on the substrate 110. Sides of the lid 160 formed downwards attach to the adhesives 140 to secure the lid 160 with the substrate 110.

As indicated above, conventional lidded packages, such as the semiconductor package 100, are mostly used in high-power applications such as in automotive platforms. However, when junction temperature Tj gets high, TIM delamination can occur. That is, delamination of the TIM 150 can occur. As a result, package warpage can grow beyond specification, which in turn can cause overheating.

To address these and other issues of the conventional semiconductor package, it is proposed to improve thermal performance of lidded IC packages by utilizing latent heat of phase change materials. As such, it is proposed to use a heat sink lid that is embedded with solid-liquid phase change material (SLPCM).

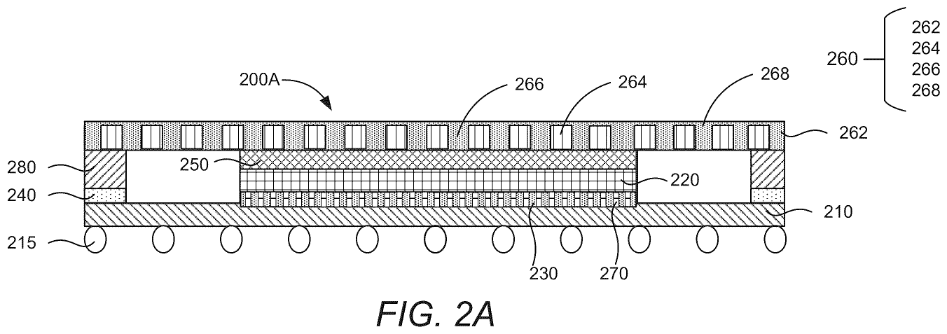

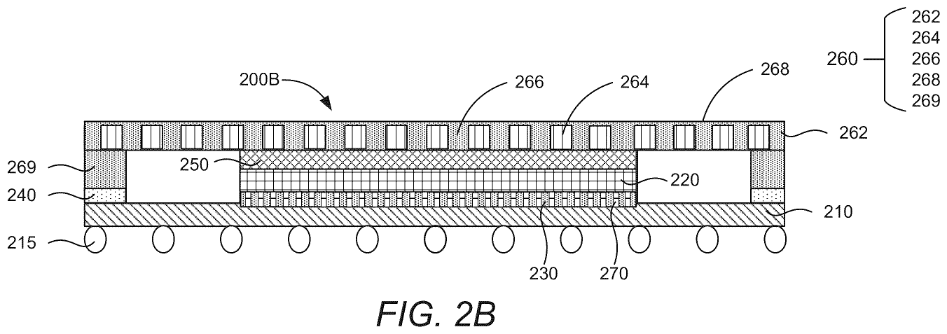

FIG. 2A illustrates a cross-sectional view of a semiconductor package 200A in accordance with one or more aspects of the disclosure. The semiconductor package 200A may include a substrate 210 with balls 215 of a ball grid array (BGA) formed on a lower surface of the substrate 210. The semiconductor package 200A may also include a die 220 on the substrate 210. The die 220 may include one or more microbumps 230 to electrically connect the die 220 with the substrate 210. Underfill 270 may fill the space between the substrate 210 and the die 220 not occupied by the one or more microbumps 230. In an aspect, the underfill 270 may be a capillary underfill, e.g., formed from epoxy resin. The capillary underfill may also include a hardener, a filler (e.g., SiO₂ filler), AND additives including flexible and adhesion promoter.

A thermal interface material (TIM) 250 may be formed or otherwise provided on an upper surface of the die 220, and a lid 260 may be formed or otherwise provided on the TIM 250. The lid 260 may be made of a thermally conductive material. In this way, heat generated by the die 220 during operation can be absorbed and dissipated by the lid 260 through the TIM 250. The TIM 250 may conform to imperfections on the surfaces of the die 220 and of the lid 260, which can lead to more efficient transfer of heat between the die 220 and the lid 260 than if the die 220 and the lid 260 are in direct contact with each other. In an aspect, the TIM 250 may be an adhesive type TIM. The adhesive may be formed from a silicone-based material with hardener and may include ceramic high thermal fillers (e.g., alumina (Al₂O₃), boron nitride (BN), etc.) and/or high thermal metal fillers (e.g., silver (Ag), copper (Cu), etc.).

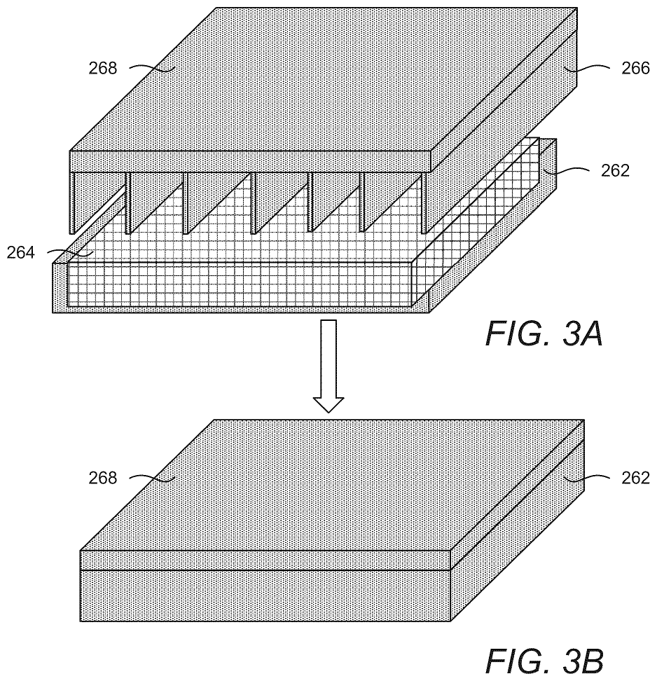

Unlike the conventional lid such as the lid 160 of FIG. 1 formed as a solid metal, the proposed lid 260 may include a solid-liquid phase change material (SLPCM) 264 within the lid 260. This is shown in FIGS. 3A and 3B. FIG. 3A shows some of the components that can be included in the lid 260. As seen, the lid 260 may include a chassis 262 (forming sides and lower portion) and a cover 268. When the chassis 262 and the cover 268 are closed as seen in FIG. 3B, the chassis 262 and the cover 268 may define an internal volume of the lid 260. One or both of the chassis 262 and/or the cover 268 may be made of thermally conductive materials such as metal (e.g., copper (Cu), aluminum (Al), etc.).

As seen in FIG. 3A, the SLPCM 264 may be provided within the internal volume of the lid 260. A technical advantage of the SLPCM 264 is that heat from the die 220 may be adsorbed by the SLPCM 264 without changing temperature while changing phases from solid to liquid (e.g., melting) utilizing the latent heat of the material. As such, a significant amount of heat can be dissipated from the die 220. For electronic devices, useful melting temperature of SLPCMs can range between 50° C. and 120° C.

Also as seen in FIG. 3A, the lid may also include one or more fins 266 within the internal volume of the lid 260. The one or more fins 266 may also be made of thermally conductive materials such as metal (e.g., Cu, Al, etc.). At least one fin 266 may be in contact with the chassis 262 and with the cover 268. This can increase the contact area between the metals of the lid (e.g., the chassis 262, the fins 266, the cover 268) and the SLPCM 264 to allow the heat from the die 220 to be distributed to more of the SLPCM 264.

Referring back to FIG. 2A, the lid 260 may comprise the chassis 262, the fins 266, the cover 268 and the SLPCM 264. One or more adhesives 240 may be formed on the substrate 210, and one or more stiffeners 280 may be formed on the one or more adhesives 240 above the substrate 210. The lid 260 may also be provided on the stiffeners 280. For example, upper surfaces of the stiffeners 280 and the TIM 250 may be at a same height. The stiffener 280 may surround the die 220 and the TIM 250. For example, the stiffener 280 may be a ring. The stiffeners 280 may be formed of metals —same or different from the lid 260. The stiffeners 280 may provide support to enhance mechanical integrity of the semiconductor package 200A.

FIG. 2B illustrates a cross-sectional view of a semiconductor package 200B in accordance with one or more aspects of the disclosure. The semiconductor package 200B can include similar components as the semiconductor package 200A. One difference between the semiconductor packages 200A and 200B is as follows. Instead of the stiffener 280, the semiconductor package 200B includes a foot 269. The foot 269 may play a role similar to that of the stiffener 280. For example, the stiffener 280 may surround the die 220 and the TIM 250 (e.g., the stiffener 280 may be a ring), and/or may enhance the mechanical integrity of the semiconductor package 200B.

Whereas the stiffener 280 can be formed separately from the lid 260, the foot 269 can be formed integrally with the lid 260. Thus, in an aspect, the lid 260 of the semiconductor package 200B may be said to include the foot 269. Being formed integrally, the foot 269 may be formed from the same metal as the lid 260. Alternatively, the foot 269 may be formed separately and provided on the lower surface of the lid 260. For example, the foot 269 may be soldered on to the lid 260. In this alternative, the lid 260 and the foot 269 may be formed of same or different metals.

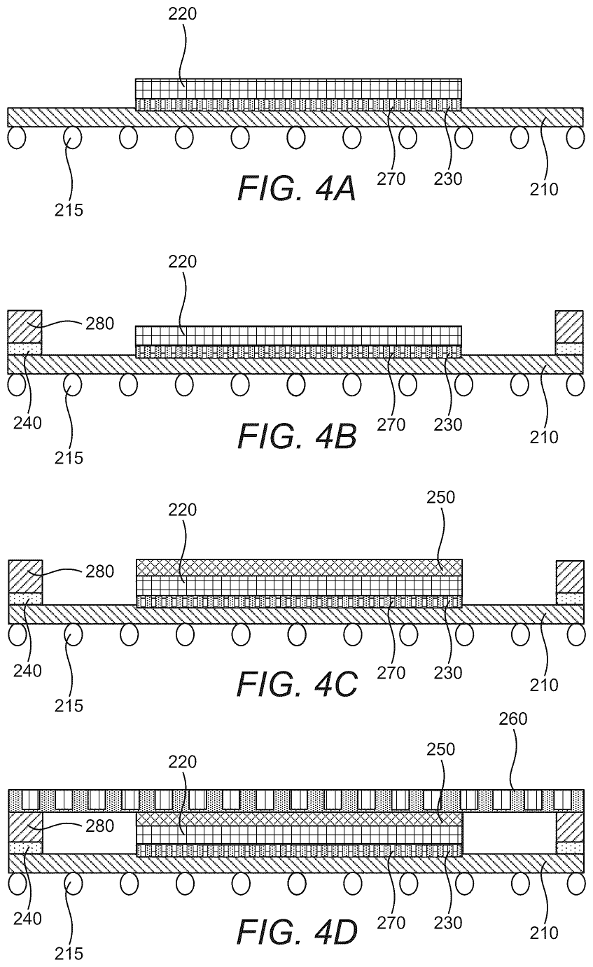

FIG. 4A-4D illustrate examples of stages of fabricating a semiconductor package, such as the semiconductor package 200A, in accordance with one or more aspects of the disclosure.

FIG. 4A illustrates a stage in which the die 220 is provided on the substrate 210.

FIG. 4B illustrates a stage in which the stiffener 280 may be attached to the substrate 210 with the adhesive 240.

FIG. 4C illustrates a stage in which the TIM 250 may be deposited on top of the die 220.

FIG. 4D illustrates a stage in which the lid 260 with the SLPCM 264 embedded therein is provided on upper surface of the TIM 250. The lid 260 may also be provided on upper surface of the stiffener 280.

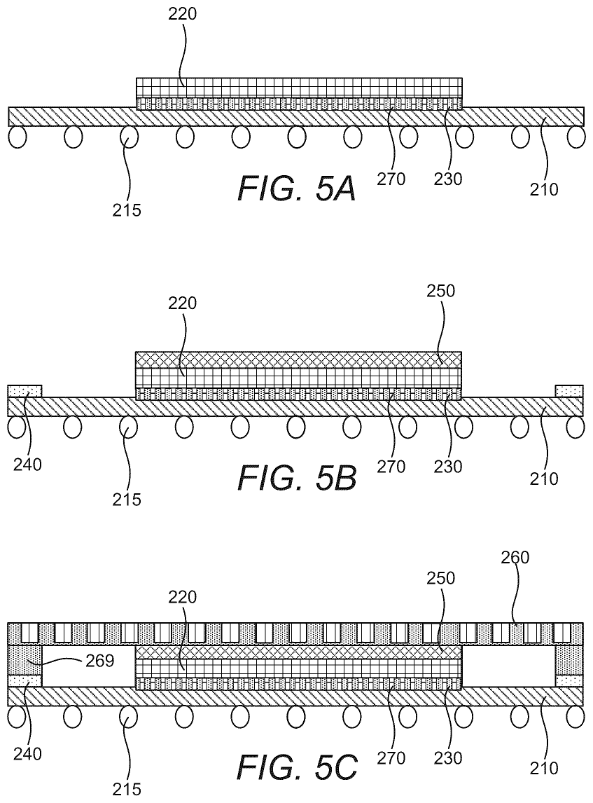

FIG. 5A-5C illustrate examples of stages of fabricating a semiconductor package, such as the semiconductor package 200B, in accordance with one or more aspects of the disclosure.

FIG. 5A illustrates a stage in which the die 220 is provided on the substrate 210.

FIG. 5B illustrates a stage in which the TIM 250 may be deposited on top of the die 220. Also, the adhesive 240 may be deposited on the substrate 210.

FIG. 5C illustrates a stage in which the lid 260 with the SLPCM 264 embedded therein is provided on upper surface of the TIM 250. In this instance, the lid 260 may include the foot 269 which may be formed integrally with the rest of the lid 260 or formed separately and attached to the lid 260 before being provided on the TIM 250. The foot 269 may be provided on the adhesive 240.

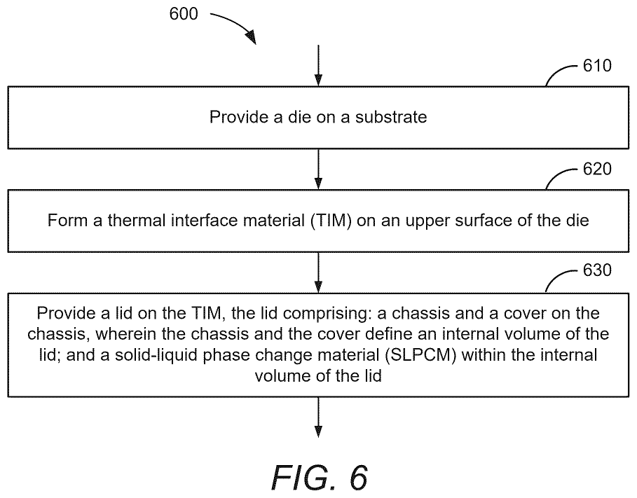

FIG. 6 illustrates a flow chart of an example method 600 of fabricating a semiconductor package, such as the semiconductor packages 200A, 200B in accordance with at one or more aspects of the disclosure.

In block 610, a die 220 may be provided on a substrate 210. Stages illustrated in FIGS. 4A and/or 5A may be analogous to block 610.

In block 620, a thermal interface material (TIM) 250 may be formed on an upper surface of the die 220. Stages illustrated in FIGS. 4C and 5B may be analogous to block 620.

In block 630, a lid 260 may be provided on the TIM 250. The lid 260 may comprise a chassis 262 and a cover 268 on the chassis 262. The chassis 262 and the cover 268 may define an internal volume of the lid 260. The lid may also comprise a solid-liquid phase change material (SLPCM) 264 within the internal volume of the lid 260. Stages illustrated in FIGS. 4D and 5C may be analogous to block 630.

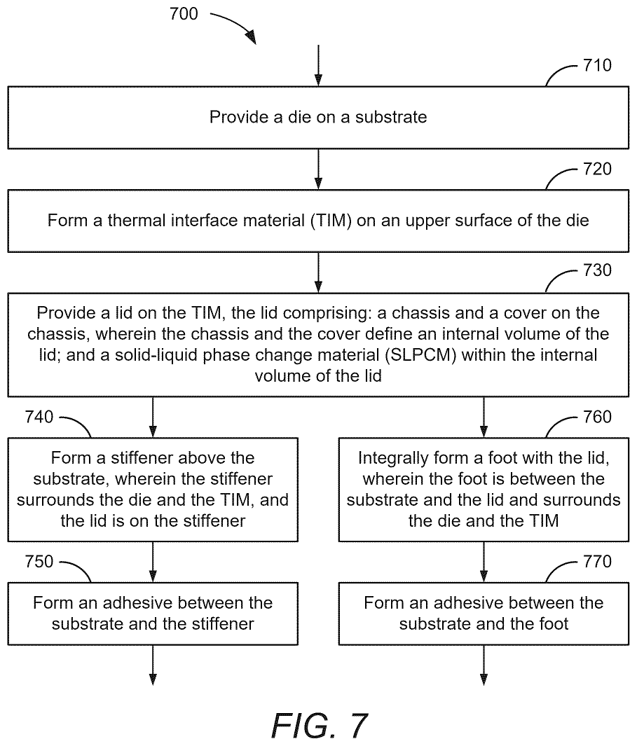

FIG. 7 illustrates a flow chart of an example method 700 of fabricating a semiconductor package, such as the semiconductor package 200A, 200B in accordance with at one or more aspects of the disclosure. FIG. 7 may be viewed as being more comprehensive than FIG. 6.

Block 710 may be similar to block 610. That is, in block 610, a die 220 may be provided on a substrate 210. Stages illustrated in FIGS. 4A and/or 5A may be analogous to block 710.

Block 720 may be similar to block 620. That is, in block 720, a thermal interface material (TIM) 250 may be formed on an upper surface of the die 220. Stages illustrated in FIGS. 4C and 5B may be analogous to block 720.

Block 730 may be similar to block 630. That is, in block 730, a lid 260 may be provided on the TIM 250. The lid 260 may comprise a chassis 262 and a cover 268 on the chassis 262. The chassis 262 and the cover 268 may define an internal volume of the lid 260. The lid may also comprise a solid-liquid phase change material (SLPCM) 264 within the internal volume of the lid 260. Stages illustrated in FIGS. 4D and 5C may be analogous to block 730.

To fabricate the semiconductor package 200A of FIG. 2A, blocks 740 and 750 may be implemented. In block 740, a stiffener 280 may be formed above the substrate 210. The stiffener 280 may surround the die 220 and the TIM 250, and the lid 260 may be on the stiffener 280. Stages illustrated in FIGS. 4B and 4D may be analogous to block 740.

In block 750, an adhesive 240 may be formed between the substrate 210 and the stiffener 280. Stage illustrated in FIG. 4B may be analogous to block 750.

To fabricate the semiconductor package 200B of FIG. 2B, blocks 760 and 770 may be implemented. In block 760, a foot 269 may be integrally formed with the lid 260. The foot 269 may be between the substrate 210 and the lid 260. The foot 269 may also surround the die 220 and the TIM 250. Stage illustrated in FIG. 5C may be analogous to block 760.

In block 770, an adhesive 240 may be formed between the substrate 210 and the foot 269. Stage illustrated in FIG. 5C may be analogous to block 770.

The following should be noted regarding the flow indicated in FIG. 6-7. Unless otherwise indicated, the flow of blocks do not necessarily limit the ordering in which the blocks may be performed. In other words, the blocks may be performed in any order that is logical.

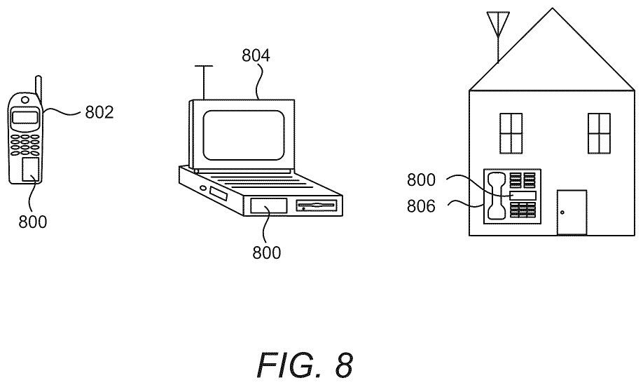

FIG. 8 illustrates various electronic devices 800 that may be integrated with any of the aforementioned semiconductor packages in accordance with various aspects of the disclosure. For example, a mobile phone device 802, a laptop computer device 804, and a fixed location terminal device 806 may each be considered generally user equipment (UE) and may include one or more semiconductor packages (e.g., semiconductor package 200A, 200B) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor package, comprising: a die on a substrate; a thermal interface material (TIM) on an upper surface of the die; and a lid on the TIM, the lid comprising: a chassis and a cover on the chassis, wherein the chassis and the cover define an internal volume of the lid; and a solid-liquid phase change material (SLPCM) within the internal volume of the lid.

Clause 2: The semiconductor package of clause 1, wherein the lid further comprises: one or more fins within the internal volume of the lid, wherein at least one fin is in contact with the chassis and with the cover.

Clause 3: The semiconductor package of clause 2, wherein any one or more of the chassis, the cover, and the one or more fins are formed from metal.

Clause 4: The semiconductor package of any of clauses 1-3, further comprising: a stiffener above the substrate, wherein the stiffener surrounds the die and the TIM, and the lid is on the stiffener.

Clause 5: The semiconductor package of clause 4, wherein the stiffener is formed from metal.

Clause 6: The semiconductor package of any of clauses 4-5, further comprising: an adhesive between the substrate and the stiffener.

Clause 7: The semiconductor package of any of clauses 1-6, further comprising: a foot integrally formed with the lid, wherein the foot is between the substrate and the lid and surrounds the die and the TIM.

Clause 8: The semiconductor package of clauses 7, wherein the foot and the lid are formed from a same metal.

Clause 9: The semiconductor package of any of clauses 7-8, further comprising: an adhesive between the substrate and the foot.

Clause 10: The semiconductor package of any of clauses 1-9, wherein a phase change temperature of the SLPCM between liquid and solid phases ranges between 50° C. and 120° C.

Clause 11: The semiconductor package of any of clauses 1-10, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 12: A method of fabricating a semiconductor package, the method comprising: providing a die on a substrate; forming a thermal interface material (TIM) on an upper surface of the die; and providing a lid on the TIM, the lid comprising: a chassis and a cover on the chassis, wherein the chassis and the cover define an internal volume of the lid; and a solid-liquid phase change material (SLPCM) within the internal volume of the lid.

Clause 13: The method of clauses 12, wherein the lid further comprises: one or more fins within the internal volume of the lid, wherein at least one fin is in contact with the chassis and with the cover.

Clause 14: The method of clauses 13, wherein any one or more of the chassis, the cover, and the one or more fins are formed from metal.

Clause 15: The method of any of clauses 12-14, forming a stiffener above the substrate, wherein the stiffener surrounds the die and the TIM, and the lid is on the stiffener.

Clause 16: The method of clauses 15, wherein the stiffener is formed from metal.

Clause 17: The method of any of clauses 12-16, further comprising: forming an adhesive between the substrate and the stiffener.

Clause 18: The method of any of clauses 12-17, further comprising: integrally forming a foot with the lid, wherein the foot is between the substrate and the lid and surrounds the die and the TIM.

Clause 19: The method of clause 18, wherein the foot and the lid are formed from a same metal.

Clause 20: The method of any of clauses 18-19, further comprising: forming an adhesive between the substrate and the foot.

Clause 21: The method of any of clauses 12-20, wherein a phase change temperature of the SLPCM between liquid and solid phases ranges between 50° C. and 120° C.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a die on a substrate;
a thermal interface material (TIM) on an upper surface of the die; and
a lid on the TIM, the lid comprising:
a chassis and a cover on the chassis, wherein the chassis and the cover define an internal volume of the lid; and
a solid-liquid phase change material (SLPCM) within the internal volume of the lid.

2. The semiconductor package of claim 1, wherein the lid further comprises:
one or more fins within the internal volume of the lid, wherein at least one fin is in contact with the chassis and with the cover.

3. The semiconductor package of claim 2, wherein any one or more of the chassis, the cover, and the one or more fins are formed from metal.

4. The semiconductor package of claim 1, further comprising:
a stiffener above the substrate,
wherein the stiffener surrounds the die and the TIM, and the lid is on the stiffener.

5. The semiconductor package of claim 4, wherein the stiffener is formed from metal.

6. The semiconductor package of claim 4, further comprising:
an adhesive between the substrate and the stiffener.

7. The semiconductor package of claim 1, further comprising:
a foot integrally formed with the lid,
wherein the foot is between the substrate and the lid and surrounds the die and the TIM.

8. The semiconductor package of claim 7, wherein the foot and the lid are formed from a same metal.

9. The semiconductor package of claim 7, further comprising:
an adhesive between the substrate and the foot.

10. The semiconductor package of claim 1, wherein a phase change temperature of the SLPCM between liquid and solid phases ranges between 50° C. and 120° C.

11. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor package, the method comprising:
providing a die on a substrate;
forming a thermal interface material (TIM) on an upper surface of the die; and
providing a lid on the TIM, the lid comprising:
a chassis and a cover on the chassis, wherein the chassis and the cover define an internal volume of the lid; and
a solid-liquid phase change material (SLPCM) within the internal volume of the lid.

13. The method of claim 12, wherein the lid further comprises:
one or more fins within the internal volume of the lid, wherein at least one fin is in contact with the chassis and with the cover.

14. The method of claim 13, wherein any one or more of the chassis, the cover, and the one or more fins are formed from metal.

15. The method of claim 12, further comprising:
forming a stiffener above the substrate,
wherein the stiffener surrounds the die and the TIM, and the lid is on the stiffener.

16. The method of claim 15, wherein the stiffener is formed from metal.

17. The method of claim 15, further comprising:
forming an adhesive between the substrate and the stiffener.

18. The method of claim 12, further comprising:
integrally forming a foot with the lid,
wherein the foot is between the substrate and the lid and surrounds the die and the TIM.

19. The method of claim 18, further comprising:
forming an adhesive between the substrate and the foot.

20. The method of claim 12, wherein a phase change temperature of the SLPCM between liquid and solid phases ranges between 50° C. and 120° C.
